(19) United States
(12) Patent Application Publication
(10) Pub. No.: US 2009/0116938 A1
(43) Pub. Date: May 7, 2009

(54) CHECK VALVE AND SUBSTRATE PROCESSING APPARATUS USING SAME

(75) Inventor: Shinji WAKABAYASHI, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/264,393

(22) Filed: Nov. 4, 2008

Related U.S. Application Data
(60) Provisional application No. 61/024,352, filed on Jan. 29, 2008.

(30) Foreign Application Priority Data
Nov. 6, 2007 (JP) 2007-288801

(51) Int. Cl. F16K 15/02; H01L 21/677

(52) U.S. Cl. 414/217.1; 137/527.8

(57) ABSTRACT

A check valve is installed in a line having a fluid path for preventing generation of a back flow in the fluid path. The check valve includes a cylindrical member in which a part of the fluid path is formed; a valve body installed in the cylindrical member and rotatable between a blocking position for blocking the fluid path and an opening position for opening the fluid path; a rotary shaft which is installed horizontally to divide the valve body into a large area and a small area and allows the valve body to rotate thereabout; and a locking member for locking the valve body in the blocking position. The small area has a larger mass than that of the large area.

### FIELD OF THE INVENTION

The present invention relates to a check valve installed in a fluid path such as a gas exhaust line or the like and a substrate processing apparatus using same.

### BACKGROUND OF THE INVENTION

A semiconductor device manufacturing process includes a process for performing, e.g., etching or the like, on a semiconductor wafer as a substrate to be processed. An apparatus for performing such processing includes a mounting table for mounting thereon a FOUP (Front Opening Unified Pod) as a transfer container accommodating therein a plurality of, e.g., 25, wafers; a processing chamber for performing a predetermined processing on a wafer; and a loading/unloading port having a transfer mechanism for loading/unloading a substrate into/from a processing unit between the FOUP on the mounting table and the processing unit. The processing chamber for performing an etching process or the like is generally maintained under a vacuum atmosphere, whereas the loading/unloading port is maintained under an atmospheric-air atmosphere. Therefore, a load-lock chamber is installed between the processing chamber and the transfer unit.

In such a processing apparatus, corrosive gases such as CxFy, HF, NH₃, HBr, Cl₂ and the like are used. Further, although the inside of the processing chamber is vacuum-exhausted, it is unavoidable that small amount of those gases, however small the amount may be, are diffused to the loading/unloading port during the transfer of the wafer. Although such a processing apparatus is installed in a clean room of a semiconductor device manufacturing facility, the loading/unloading port is in an atmospheric-air atmosphere. When the corrosive gases are diffused into the loading/unloading port, they are directly diffused into the clean room, thus rusting the equipments or doing harm to human body.

In order to prevent the diffusion of the corrosive gases, a fan filter unit serving for supplying clean air into the transfer unit is installed on a ceiling portion of the transfer unit. Moreover, a plurality of gas exhaust channels (gas exhaust lines) connected to a factory exhaust line is installed on a bottom portion of the transfer unit, so that the corrosive gases can be exhausted without being diffused into the clean room. When these gas exhaust channels are directly connected to the factory exhaust line, a check valve is installed in order to reliably prevent a back flow of the corrosive gases from the factory exhaust line.

The check valve is required to have a simple structure capable of effectively preventing the back flow of the gases of corrosive components from the factory exhaust line. As for the check valve, there is used a swing check valve described in Patent Document 1. That is, this swing check valve is installed in a line while being supported by a hinge. In this structure, when flow occurs in the forward direction (normal flow), the swing valve is rotated about the hinge to be kept opened. On the contrary, when the back flow occurs, the swing valve is closed to seal a flow path.

Moreover, Patent Document 2 discloses a check valve using a coil spring. A valve body is installed in a flow path in a state of being closed by pressing force of the spring. When the normal flow occurs, the valve body opens against the pressing force of the coil spring, whereas when the back flow occurs, the valve is closed.

[Patent Document 1] Japanese Patent Laid-open Publication No. H7-269727

[Patent Document 2] Japanese Patent Laid-open Publication No. H5-215260

The technique using the swing valve disclosed in Patent Document 1 is applied only to a horizontal flow path or a substantially horizontal flow path, not to a vertical flow path, which restricts a layout. Further, when the gas exhaust channel extends downward from the bottom portion of the transfer unit, a horizontal portion needs to be provided in the middle of the gas exhaust channel. This requires a large space and restricts the arrangement position of the gas exhaust channel.

Although the technique using the coil spring disclosed in Patent Document 2 does not have the space limitation problem, it is disadvantageous in that the structure is complicated. Therefore, this technique is not suitable for a line through which a corrosive gas flows.

### SUMMARY OF THE INVENTION

In view of the above, the present invention provides a check valve which has a simple structure with no space limitation problem.

Further, the present invention provides a substrate processing apparatus using the check valve.

In accordance with an aspect of the present invention, there is provided a check valve installed in a line having a fluid path, for preventing generation of a back flow in the fluid path.

The check valve includes a cylindrical member in which a part of the fluid path is formed; a valve body installed in the cylindrical member and rotatable between a blocking position for blocking the fluid path and an opening position for opening the fluid path; a rotary shaft which is installed horizontally to divide the valve body into two parts and allows the valve body to rotate thereabout; and a locking member for locking the valve body in the blocking position.

When a first moment is given as a moment applied to the valve body with respect to the rotary shaft by a pressure difference between an upstream side and a downstream side of the valve body due to flow in the fluid path and a second moment is given as a moment applied to the valve body by gravity, the position of the rotary shaft dividing the valve body into two parts and the masses of respective areas of two parts of the valve body are set.

Accordingly, in a case of forward flowing in the fluid path, the first moment and the second moment react in opposite directions such that when the pressure difference is greater than a predetermined value, the first moment becomes greater than the second moment, thereby rotating the valve body to an opening position, and when the pressure difference is equal to or less than the predetermined value, the first moment becomes smaller than the second moment, thereby rotating the valve body to a blocking position. In a case of back flowing in the fluid path both of the first moment and the second moment react in a direction of rotating the valve body to the blocking position.

The rotary shaft preferably divides the valve body into a relatively large area and a relatively small area having a larger mass than that of the relatively large area.

The relatively small area may have a weight.

Preferably, the check value further includes a stopper which limits rotation of the valve body within about 90° when the valve body is in an opening position.

The fluid path of the line is preferably formed in a vertical direction.

Preferably, the valve body has a rectangular shape; the cylindrical member has a cross section of a rectangular shape corresponding to the shape of the valve body; and the valve body is installed in a rectangular-shaped line.

The check valve is preferably used in a gas exhaust line installed in a substrate processing apparatus for processing a substrate to be processed by using a corrosive gas.

In accordance with another aspect of the present invention, there is provided a substrate processing apparatus for performing a predetermined processing on a substrate to be processed by using a corrosive gas.

The substrate processing apparatus includes a processing unit for performing the predetermined processing by using the corrosive gas; a loading/unloading port for loading/unloading the substrate with respect to the processing unit; a gas exhaust line having a gas exhaust channel for exhausting the loading/unloading port to a gas exhaust channel; and a check valve installed in the gas exhaust line.

The check valve has a structure described in the above aspect.

In accordance with the aspects of the present invention, a moment applied to the valve body with respect to the rotary shaft by a pressure difference between an upstream side and a downstream side of the valve body due to the flow in the fluid path is set to a first moment and, also, a moment applied to the valve body by gravity is set to a second moment. When the forward flow occurs in the fluid path, the first moment and the second moment react in opposite directions. If the pressure difference is greater than a predetermined value, the first moment becomes greater than the second moment, so that the valve body rotates to an opening position. If the pressure difference is smaller than a predetermined value, the first moment becomes smaller than the second moment, so that the valve body rotates to a blocking position. On the contrary, when the back flow occurs in the fluid path, the first moment and the second moment react in a direction of rotating the valve body to the blocking position. The position of the rotary shaft dividing the valve body into two parts and the masses of two parts of the valve body which are divided by the rotary shaft are properly set to enable the above-described manner of rotations of the valve body. To be specific, the valve body is divided by the rotary shaft into a relatively large area and a relatively small area, and the mass of the relatively small area is set to be greater than that of the relatively large area. Accordingly, the check valves can be installed even in a vertical fluid path successively, which increases a degree of freedom in design layout. Further, unlike in the conventional swing check valve, a horizontal path is not required and, thus, the occupation space can be reduced. Furthermore, since there is no need to install additional mechanisms such as a coil spring and the like, the structure can be simplified. Besides, the check valve of the present invention can be applied to a line where a corrosive gas flows.

### BRIEF DESCRIPTION OF THE DRAWINGS

The objects and features of the present invention will become apparent from the following description of embodiments, given in conjunction with the accompanying drawings, in which:

FIG. 1 is a top view of a processing apparatus in which a check valve in accordance with an embodiment of the present invention is installed in a gas exhaust channel;

FIG. 2 describes a cross sectional view of a loading/unloading port of the processing apparatus of FIG. 1;

FIGS. 3A and 3B provide a vertical cross sectional view and a horizontal cross sectional view of the check valve in accordance with the embodiment of the present invention;

FIG. 4 presents a cross sectional view of a conventional swing check valve;

FIG. 5 schematically shows a state where the conventional swing check valve is installed in a T-shaped line; and

FIG. 6 offers a horizontal cross sectional view of a modification of the check valve of the present invention.

### DETAILED DESCRIPTION OF THE EMBODIMENTS

The embodiments of the present invention will be described with reference to the accompanying drawings which form a part hereof.

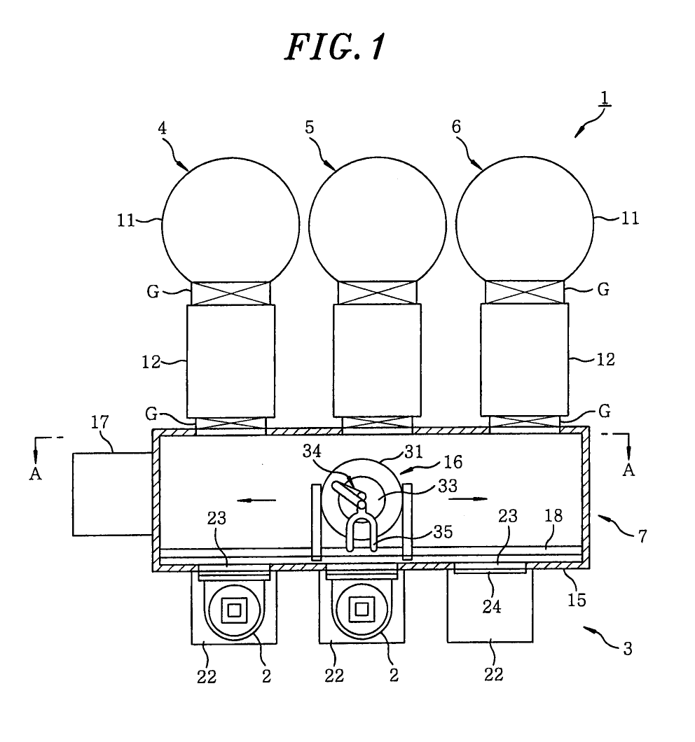

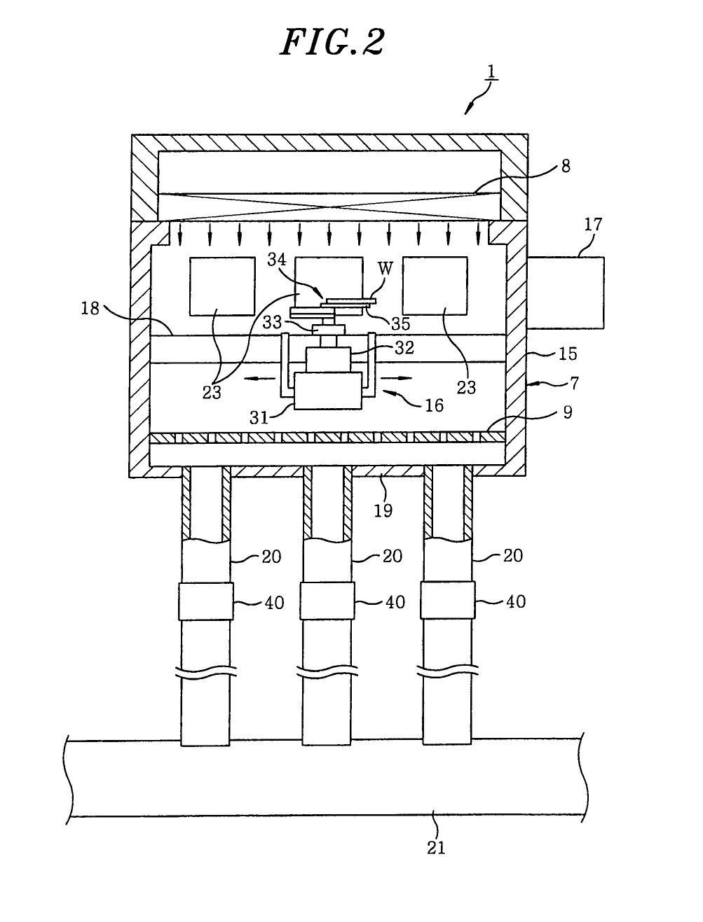

FIG. 1 shows a top view of a processing apparatus in which a check valve in accordance with an embodiment of the present invention is installed in a gas exhaust channel, and FIG. 2 is a cross sectional view of a loading/unloading port of the processing apparatus, which is taken along line A-A of FIG. 1.

A processing apparatus 1 is a single wafer processing apparatus in which semiconductor wafers (hereinafter, simply referred to as “wafers”) as substrates to be processed are successively transferred and subjected to, e.g., an etching process. The processing apparatus 1 is installed in a clean room maintained under a clean atmosphere. Further, the processing apparatus 1 includes: a mounting table 3 for mounting thereon FOUPs 2, each serving as a transport container accommodating therein a plurality of, e.g., 25, wafers W; three process ships 4, 5 and 6 serving as processing units for performing a predetermined processing, e.g., etching, on the wafer W; and a loading/unloading chamber 7 for loading the wafer W from the FOUP 2 on the mounting table 3 into the process ships 4 to 6 and unloading the wafer W from the process ships 4 to 6 into the FOUP 2. Installed at an upper portion of the loading/unloading chamber 7 is a fan filter unit (FFU) 8 for supplying a downward flow of clean air into an inner space of the loading/unloading chamber 7 (see, FIG. 2).

Each of the process ships 4 to 6 includes a processing chamber 11 for performing a predetermined processing on the wafer W; and a load-lock chamber 12 having therein a transfer arm (not shown) for transferring the wafer W to and from the processing chamber 11, wherein the load-lock chamber 12 can be kept under a vacuum atmosphere as well as under an atmospheric-air atmosphere. As for the processing chamber 11, there is used a cylindrical processing vessel (chamber) for performing a plasma etching on a predetermined film of the wafer W by introducing a halogen containing processing gas such as CxFy, HBr, Cl₂ or the like thereinto and generating a plasma of the processing gas, or a processing vessel for performing an isotropic etching by introducing a corrosive gas (e.g., NH₃) and HF thereinto and performing a COR (Chemical Oxide Removal) process on a predetermined film of the wafer W without using an electric field.

In each of the process ships 4 to 6, the processing chamber 11 is maintained under a vacuum atmosphere, and the load-lock chamber 12 can be kept under a vacuum atmosphere having a pressure substantially the same as that of the processing chamber 11 or under an atmospheric-air atmosphere same as that of the loading/unloading chamber 7. The wafer W can be transferred by an internal transfer arm between the load-lock chamber 12 and the processing chamber 11 of the vacuum state. Openable/closable gate valves G are provided between the loading/unloading chamber 7 and the load-lock chamber 12 and between the load-lock chamber 12 and the processing chamber 11, respectively.

The loading/unloading chamber 7 has a housing 15 elongated in a longitudinal direction (X direction) along which the FOUPs 2 are arranged, and a transfer mechanism 16 is installed in the housing 15. Connected to a side portion of the housing 15 is an orienter 17 for aligning the wafers W (i.e., positions of orientation flats or notches) loaded from the FOUPs 2 to the loading/unloading chamber 7. As shown in FIG. 2, the transfer mechanism 16 includes an X-direction moving unit 31 that is movable along a guide rail 18 installed in the X direction in the housing 15; a Z-direction moving unit 32 installed on the X-direction moving unit 31 to be movable in a vertical direction (Z direction); a turn table 33 disposed on the Z-direction moving unit 32; and a multi-joint transfer arm 34 provided on the turn table 33. The transfer arm 34 has at a leading end thereof a pick 35 for supporting the wafer W.

As illustrated in FIG. 2, a vent plate 9 made of a punching metal is disposed at the bottom portion of the loading/unloading chamber 7, and a bottom plate 19 is provided thereunder. Connected to the bottom plate 19 are gas exhaust lines 20 forming a plurality of (three in FIG. 2) gas exhaust paths. By discharging clean air received from the FFU 8 downward via the gas exhaust lines 20 with the use of a fan (not shown) installed at the bottom portion of the loading/unloading chamber 7, a downward flow of clean air is formed in the housing 15, and the inner space of the housing 15 is maintained under a clean mini-environment. The gas exhaust lines 20 vertically extend downward, and are connected to a factory exhaust line 21 extending horizontally below the processing apparatus 1. The exhaust gas such as a halogen compound or the like discharged from the processing chamber 11 or the like flows in the factory exhaust line 21. Thus, in order to prevent a back flow of the exhaust gas, check valves 40 of the present embodiment are installed in the middle of the gas exhaust lines 20.

The mounting table 3 has three FOUP mounting tables 22 installed along the X direction on the sidewall of the housing 15 of the loading/unloading chamber 7 which is the sidewall opposite to the side where the process ships 4 to 6 are disposed. Further, in the housing 15, windows 23 are provided at positions corresponding to the FOUP mounting tables 22, and loading/unloading gates (openers) 24 are installed at the windows 23, respectively. The wafer W can be loaded and unloaded by opening the openers 24 while the FOUP 2 is mounted on the FOUP mounting table 22 and the housing 15 is sealed.

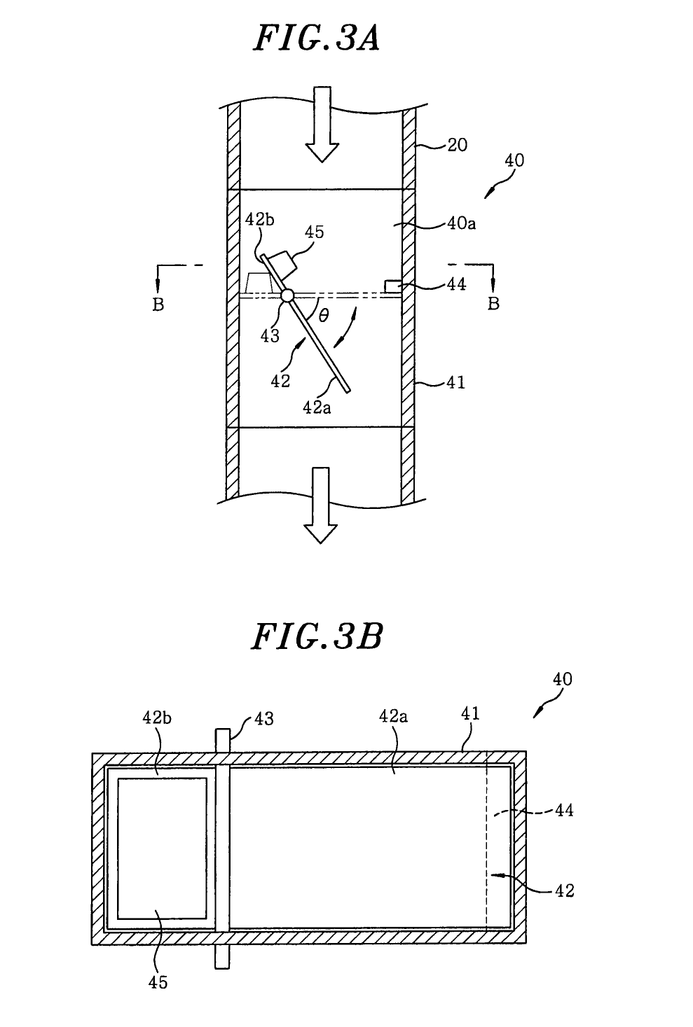

Hereinafter, the check valve 40 of the present embodiment will be described with reference to FIGS. 3A and 3B. FIG. 3A is a vertical cross sectional view of the check valve 40, and FIG. 3B is a horizontal cross sectional view taken along the line B-B of FIG. 3A.

The check valve 40 is installed in the middle of the gas exhaust line 20 and includes a cylindrical member 41 having a rectangular cross section, in which a gas exhaust path 40a is formed; a valve body 42 capable of blocking the gas exhaust path 40a in the cylindrical member 41; a rotary shaft 43 installed horizontally to support the valve body 42 and rotatable between a blocking position for blocking a flow path and an opening position for opening the flow path; and a locking member 44 for locking the valve body 42 in a blocking position.

The rotary shaft 43 is installed to divide the valve body 42 into a relatively large area 42a and a relatively small area 42b. The small area 42b has a weight 45 and thus has a larger mass than that of the large area 42a.

Here, the area and the mass of the large area 42a are set to S1 and m1, and the area and the mass of the small area 42b are set to S2 and m2, respectively. When the flow occurs in the forward direction (the flow from the housing 15 to the factory exhaust line 21, hereinafter, referred to as a “normal flow”), a pressure difference between an upstream side and a downstream side of the valve body 42 (upstream side pressure being higher) is set to ΔP1. Since the rotary shaft 43 is installed in a horizontal direction, a moment in a counterclockwise direction of blocking the flow path is set to (m2-m1)·g (g indicating acceleration of gravity), and a moment in a clockwise direction of opening the flow path is set to (S1-S2)·ΔP1. Thus, in order to open the valve body 42 during the normal flow, the condition of (S1-S2)·ΔP1>(m2-m1)·g needs to be satisfied.

This can be modified as: ΔP1>{(m2-m1)g}/(S1-S2).

If (S1-S2)·ΔP1 is smaller than or equal to (m2-ml)·g even during the normal flow, the moment (S1-S2)·ΔP1 applied in the direction of opening the flow path decreases, so that the valve body 42 is not opened and is locked. Meanwhile, when the flow occurs in the reverse direction (the flow from the factory exhaust line 21 to the housing 15, hereinafter, referred to as a “back flow”), a pressure difference between an upstream side and a downstream side (downstream side pressure being higher) is set to ΔP2. At this time, the moment (m2-m1)·g and the moment (S1-S2)·ΔP2 are applied in the same direction, i.e., in the counterclockwise direction. Hence, the valve body 42 is locked reliably.

Therefore, by setting m1, m2, S1 and S2 to satisfy the aforementioned equations, the check valve can be installed even in a vertical gas exhaust path. In that case, it is preferable to install a stopper so that the valve body 42 is opened within an opening degree of about 90°. That is, if the opening degree exceeds 90° for any reason, it is difficult to return the valve body 42 to the blocking position.

In order to unitize the check valves, it is preferable that the cylindrical members 41 are provided separately from the gas exhaust line 20. However, the cylindrical member 41 may be installed as a part of the gas exhaust line 20. Further, in order to prevent the back flow reliably, there may be provided a sealing member which seals the gas exhaust paths when the valve body 42 reaches the blocking position.

Hereinafter, the operation of the processing apparatus 1 will be explained.

First of all, the FOUP 2 accommodating therein a plurality of, e.g., 25, wafers W is mounted on any one of the three FOUP mounting tables 22 of the mounting table 3, and the opener 24 opens so that the wafers W can be loaded. Next, the wafers W are unloaded from the FOUP 2 one by one by using the transfer mechanism 16, and transferred into the orienter 17 for aligning the orientation of the wafers W. Then, the wafer W is loaded into the load-lock chamber 12 connected to any one of the process ships 4 to 6.

In a state where the gate valves G are closed, the load-lock chamber 12 is exhausted from the atmospheric-air atmosphere to a vacuum state of a pressure substantially same as that of the processing chamber 11. Thereafter, the gate valve of the processing chamber 11 side is opened, and the wafer W is transferred to the processing chamber 11 by the transfer arm (not shown) disposed in the load-lock chamber 12.

In the processing chamber 11, as described above, a predetermined film of the wafer W is etched by a plasma etching processing, a COR processing or the like by using a corrosive gas such as CxFy, HF, NH₃, HBr, Cl₂ or the like.

After the processing in the processing chamber 11 is completed, the wafer W is restored to the load-lock chamber 12, and the vacuum atmosphere is changed into the atmospheric-air atmosphere in a state where the corresponding gate valves G of the load-lock chamber 12 are closed. Next, the gate valve G of the loading/unloading chamber 7 side is opened, and the wafer W in the load-lock chamber 12 is transferred by the transfer mechanism 16 to an empty FOUP 2 mounted on any one of the three FOUP mounting tables 22 of the mounting table 3. The wafer W may also be transferred to the same FOUP 2 from which it had been unloaded.

At this time, the processing chamber 11 is vacuum-exhausted. Further, although the gate valves G exist between the processing chamber 11 and the load-lock chamber 12 and between the load-lock chamber 12 and the housing 15 of the loading/unloading chamber 7, the corrosive gases such as CxFy, HF, NH₃, HBr, Cl₂ and the like, however small the amount may be, are diffused to the loading/unloading chamber 7 during the loading/unloading of the wafer W into/from the processing chamber 11. Further, by-products containing corrosive components which remain on the substrate are diffused as corrosive gases in the loading/unloading chamber 7. In order to prevent the diffusion of the corrosive gases from the loading/unloading chamber 7 to the clean room, clean air is made to flow from the FFU 8 into the housing 15 of the loading/unloading chamber 7 and then to flow into the gas exhaust lines 20 by the fan. By forming the downward flow of clean air, the corrosive gases are drawn into the factory exhaust line 21 via the gas exhaust lines 20. As a consequence, the diffusion of the corrosive gases into the clean room can be reliably prevented.

In this case, due to the presence of the check valves 40 provided in the gas exhaust lines 20, the corrosive gases such as a halogen containing gas and the like flowing in the factory exhaust line 21 can be prevented from back-flowing to the loading/unloading chamber 7. Each of the check valves 40 is installed to be rotatable about the rotary shaft 43 between the blocking position for blocking the flow path and the opening position for opening the flow path, as described above. Further, the valve body 42 is divided into the large area 42a and the small area 42b, and the small area 42b has a larger mass than that of the large area 42a. The valve body 42 is opened only when (S1-S2)·ΔP1 is greater than (m2-m1) *g, i.e., when the pressure difference ΔP1 is greater than a specific value, during the normal flow. The valve body 42 is closed when the pressure difference ΔP1 equal to or less than the specific value or when the back flow occurs.

Accordingly, even if the flow path is formed in a vertical direction, when the normal flow occurs, the gas can be exhausted in a state where the valve body 42 is opened within a predetermined angle. Besides, when the back flow occurs, the valve body 42 is closed to reliably prevent the gases from flowing from the factory exhaust line 21 into the housing 15. As a result, unlike the conventional swing valve, the check valve does not necessarily require a horizontal flow path, which increases a degree of freedom of design layout.

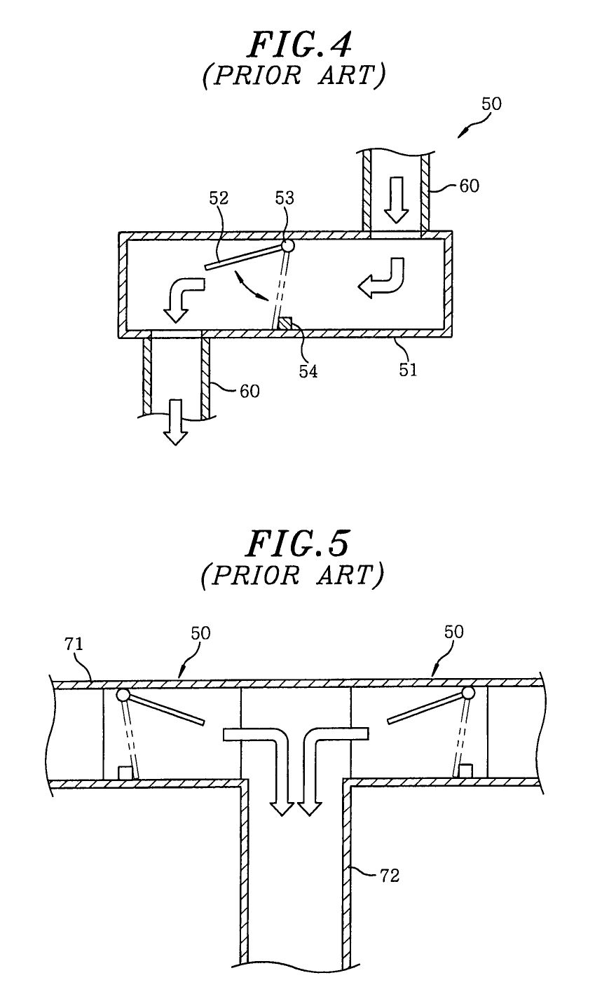

In other words, in the conventional swing check valve 50 shown in FIG. 4, a cylindrical member 51 is installed horizontally to form a horizontal flow path, and a swing type valve body 52 is installed to be rotatable about the rotary shaft 53. When the normal flow occurs, the valve body 52 is opened, whereas when the back flow occurs, the valve body 52 is locked by the locking member 54 and is maintained in the position of blocking the flow path. Accordingly, the check valve cannot be installed in a vertical flow path, which decreases a degree of freedom of design layout.

Moreover, when the conventional swing check valve 50 is installed in a vertical gas exhaust line 60 as illustrated in FIG. 4, the flow path needs to be horizontal at a portion where the check valve 50 is installed, requiring a large occupying space. Further, when the conventional check valve is applied to a T-shaped line formed by a horizontal line 71 and a vertical line 72 as depicted in FIG. 5, in order to prevent a back flow from a downstream side of the vertical line 72 to the horizontal line 71, two check valves 50 need to be installed in such a way that the vertical line 72 is provided therebetween.

On the contrary, the check valves 40 of the present embodiment can be installed even in a vertical flow path. Further, they can be installed in a vertical gas exhaust line successively, so that an occupying space can be reduced. Further, the cylindrical body 41 can be installed to be a part of the gas exhaust line 20, as a unit with the gas exhaust line 20. In that case, the occupying space can be further decreased. In order to unitize the check valves, it is preferable to provide the cylindrical body 41 separately from the gas exhaust line 20.

Since the check valve 40 of the present embodiment can be installed in a vertical flow path, when they are applied to a T-shape line, they can be installed in a vertical line. Therefore, the number of the check valves 40 of the present embodiment can be reduced compared to that of the conventional check valves 50.

Moreover, each of the check valves 40 of the present embodiment is configured to have the valve body 42 to be rotatable about the rotary shaft 43 and to provide the weight 45 at the small area 42b, and thus has a simple structure as the conventional swing check valve. Therefore, it is easy to cope with the corrosive gases, and the components of the check valve 40 may be installed in a line where the corrosive gases flow. However, in the check valve having a complicated mechanism using a coil spring or the like, it is difficult to cope with the corrosive gases and, thus, it is not preferable to install the components in a line where the corrosive gases flow.

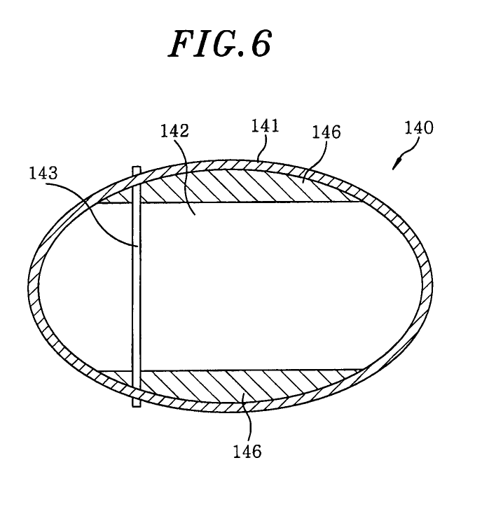

Further, the present invention can be variously modified without being limited to the above embodiments. For example, the cylindrical member has a rectangular cross section in the above embodiments, but may have another shaped cross section such as an elliptic cross section or a circular cross section. For example, in a check valve 140 having a cylindrical member 141 of an elliptic cross section shown in FIG. 6, a gap needs to be formed between a valve body 142 and the cylindrical member 141 so that the valve body 142 can rotate and, also, it is preferable to install a sealing member 146 in order to prevent the back flow from the gap. This is also applied when the cylindrical member has a circular cross section. When the cylindrical member has a rectangular cross section as in the above embodiments, even if the valve body has a cross section same as that of the cylindrical member, the valve body can rotate regardless of the position of the rotary shaft. A reference numeral 143 indicates a rotary shaft.

Moreover, the check valve of the present invention is not necessarily installed in a gas exhaust line having a vertical flow path.

Further, in the above embodiments, the check valves of the present invention are installed in gas exhaust lines of a loading/unloading port of an atmospheric-air atmosphere in a processing apparatus such as an etching apparatus or the like. However, they may be installed at other portions of the gas exhaust lines, such as at a downstream side of a vacuum pump of a vacuum processing unit or the like. Furthermore, they may be installed in gas supply paths other than the gas exhaust line. In addition, fluid flowing in a flow path may be liquid without being limited to gas.

The present invention is generally applied to a check valve having a purpose of preventing a back flow of fluid, and is especially suitable for a check valve installed in a gas exhaust line for exhausting a corrosive gas in a semiconductor device processing apparatus.

While the invention has been shown and described with respect to the embodiment, it will be understood by those skilled in the art that various changes and modification may be made without departing from the scope of the invention as defined in the following claims.

What is claimed is:

1. A check valve installed in a line having a fluid path, for preventing generation of a back flow in the fluid path, the check valve comprising:
a cylindrical member in which a part of the fluid path is formed;
a valve body installed in the cylindrical member and rotatable between a blocking position for blocking the fluid path and an opening position for opening the fluid path;
a rotary shaft which is installed horizontally to divide the valve body into two parts and allows the valve body to rotate thereabout; and
a locking member for locking the valve body in the blocking position,
wherein when a first moment is given as a moment applied to the valve body with respect to the rotary shaft by a pressure difference between an upstream side and a downstream side of the valve body due to flow in the fluid path and a second moment is given as a moment applied to the valve body by gravity, the position of the rotary shaft dividing the valve body into two parts and the masses of respective areas of two parts of the valve body are set in such a way that in a case of forward flowing in the fluid path, the first moment and the second moment react in opposite directions such that when the pressure difference is greater than a predetermined value, the first moment becomes greater than the second moment, thereby rotating the valve body to an opening position, and when the pressure difference is equal to or less than the predetermined value, the first moment becomes smaller than the second moment, thereby rotating the valve body to a blocking position; and in a case of back flowing in the fluid path both of the first moment and the second moment react in a direction of rotating the valve body to the blocking position.

2. The check valve of claim 1, wherein the rotary shaft divides the valve body into a relatively large area and a relatively small area having a larger mass than that of the relatively large area.

3. The check value of claim 2, wherein the relatively small area has a weight.

4. The check value of claim 1, further comprising a stopper which limits rotation of the valve body within about 900 when the valve body is in an opening position.

5. The check valve of claim 1, wherein the fluid path of the line is formed in a vertical direction.

6. The check valve of claim 1, wherein the valve body has a rectangular shape; the cylindrical member has a cross section of a rectangular shape corresponding to the shape of the valve body; and the valve body is installed in a rectangular-shaped line.

7. The check valve of claim 1, wherein the check valve is used in a gas exhaust line installed in a substrate processing apparatus for processing a substrate to be processed by using a corrosive gas.

8. A substrate processing apparatus for performing a predetermined processing on a substrate to be processed by using a corrosive gas, comprising:
a processing unit for performing the predetermined processing by using the corrosive gas;
a loading/unloading port for loading/unloading the substrate with respect to the processing unit;
a gas exhaust line having a gas exhaust channel for exhausting the loading/unloading port to a gas exhaust channel; and
a check valve installed in the gas exhaust line,
wherein the check valve has a structure described in claim 1.
